(19) United States
(12) Patent Application Publication
(10) Pub. No.: US 2014/0167804 A1
(43) Pub. Date: Jun. 19, 2014

(54) ASSEMBLY FOR OPTICAL BACKSIDE FAILURE ANALYSIS OF FLIP-CHIPS DURING ELECTRICAL TESTING

(71) Applicant: QUALCOMM INCORPORATED, San Diego, CA (US)

(72) Inventors: Himaja H. Bhatt, San Diego, CA (US); Martin E. Parley, Carlsbad, CA (US)

(73) Assignee: QUALCOMM INCORPORATED, San Diego, CA (US)

(21) Appl. No.: 13/717,245

(22) Filed: Dec. 17, 2012

(51) Int. Cl. G01R 1/04

(52) U.S. Cl. CPC G01R 1/0433
USPC 324/756.02

(57) ABSTRACT

A method and apparatus for testing a digital device. An apparatus for facilitating testing a digital device comprises a flat-top socket and a flat-top carrier board. The flat-top socket has a recess for accepting a carrier board, the recess having electrical contacts disposed in a pattern matching a pattern on a digital device. The flat-top carrier board also has a pattern of electrical contacts that match those on a digital device. A further embodiment provides an apparatus for facilitating testing of a digital device. The apparatus includes a digital device electrically and mechanically attached to a flip-chip carrier and also includes a flip-chip socket having an interface for connecting with the flip-chip carrier and an existing socket.

### BACKGROUND

1. Field

The present disclosure relates generally to testing electronic packages, and more particularly, to testing integrated circuit devices using an optical diagnostic tool.

2. Background

Traditionally integrated circuit (IC) devices were electrically tested using a test board, socket, and lid. The socket is mounted on the test board and the device to be tested is placed in the socket. Electrical contact is ensured by pressing the top of the device with a lid, to force the device contacts to meet the sockets solder balls, or electrical contacts. A flat-top socket assembly is used to carry out the failure analysis of the backside of the flip-chip die.

In order to analyze the device, the entire die must be exposed because the optical diagnostic tool of the failure analysis took must come into contact with the backside of the die and be able to move all the way to the edge of the die. One example of an optical diagnostic tool is a solid immersion lens (SIL). Few devices are as large as the optical diagnostic tool. When large dies are exposed, the device edge becomes very thin and may easily be damaged from the pressure exerted by the SIL during the testing process. Once the back cover of the device has been removed, the device may be only one-third as thick as it was originally. The die will crack when tested with a conventional socket and lid because the conventional lid applies force from the top of the device.

There is a need in the art for a mechanism to test a device without cracking it and that provides unobstructed access to the back of the die during the testing process.

### SUMMARY

Embodiments disclosed herein provide a method and apparatus for testing a digital device. An apparatus for facilitating testing a digital device comprises a flat-top socket and a flat-top carrier board. The flat-top socket has a recess for accepting a carrier board, the recess having electrical contacts disposed in a pattern matching a pattern on a digital device. The flat-top carrier board also has a pattern of electrical contacts that match those on a digital device.

A further embodiment provides an apparatus for facilitating testing of a digital device. The apparatus includes a digital device electrically and mechanically attached to a flip-chip carrier and also includes a flip-chip socket having an interface for connecting with the flip-chip carrier and an existing socket.

A still further embodiment provides a method of testing a digital device. The method includes reflowing or affixing a flip-chip package containing a digital device onto a carrier board. The flip-chip die is then exposed by parallel lapping. The flat-top socket is then installed on a load board. The carrier board is then mounted onto the carrier board is mounted on the flat-top socket. The digital device is then tested.

Yet a further embodiment provides an apparatus for facilitating testing of a digital device. The digital device comprises: means for affixing a flip-chip package containing a digital device onto a carrier board; means for exposing the flip-chip die by parallel lapping; means for installing a flat top socket on a load board; means for mounting the carrier board on the flat-top socket; and means for testing the digital device.

A further embodiment provides a non-transitory computer readable medium containing instructions, which when executed by a processor causes the processor to perform the steps of: activating an optical diagnostic tool; positioning the optical diagnostic tool over a digital device affixed onto a flat-top carrier board and electrically connected to a flat-top socket in turn electrically connected to a flat-top carrier board and a load board; and accessing the digital device for testing the solid immersion lens.

### BRIEF DESCRIPTION OF THE DRAWINGS

FIG. 1 depicts the problems with conventional testing techniques.

FIG. 2 illustrates a flat-top socket, flip-chip socket and carrier board according to an embodiment of the invention.

FIG. 3A depicts an unassembled flat-top socket, flip-chip carrier, flip-chip, and existing ball grid array (BGA) socket, according to an embodiment of the invention.

FIG. 3B depicts an assembled flat-top socket, flip-chip carrier, flip-chip, and existing BGA socket, according to an embodiment of the invention.

FIG. 4 provides a flow chart of a method of testing an integrated circuit device according to an embodiment of the invention.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

IC devices have been tested using a test board, socket, and lid. The socket is mounted on the test board and the device to be tested is placed in the well of the socket. Electrical contact is provided by pressing the top of the device with a lid, thus forcing the device contacts into contact with the socket contacts, which may be solder balls or contacts.

The flat-top socket assembly is used to test the device and carry out the failure analysis of the back side of the flip-chip die. In order to analyze the device, the entire die must be exposed so that the optical diagnostic tool may come into contact with the back side of the die. Theoptical diagnostic tool must be able to move completely over the die, and must be able to move all the way to the edge of the die. Very few devices are as large as the optical diagnostic tool. When such large dies are exposed, the device edge becomes significantly thinner, and may be only one-third as thick as originally manufactured. The thinness of this edge makes the die subject to pressure from the optical diagnostic tool during testing. A conventional socket and lid may cause cracking because the lid applies force from the top of the device.

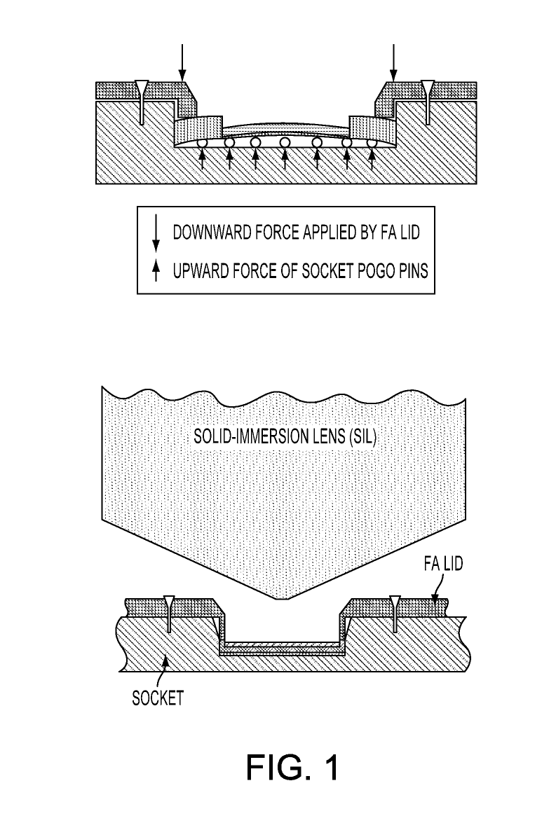

FIG. 1 illustrates the problem with conventional sockets and failure analysis lids. The first side view shows the forces exerted by the failure analysis lid pressing downward on the thinned die. An upward force is exerted by the device pogo pins. The second side view illustrates a further problem with conventional failure analysis lids. The lid does not permit the optical diagnostic tool to access all the exposed back surface of the die. The optical diagnostic tool is large in size, compared to the package size. The failure analysis lead forms the electrical connection and has an opening based on the package size. The optical diagnostic tool must come through the opening. As shown in the illustration, the opening is not large enough to allow the optical diagnostic tool access to the entire surface of the die.

Embodiments described herein provide a method and apparatus to reduce cracking of dies during testing and also allows the optical diagnostic tool unobstructed access to the back of the die for testing.

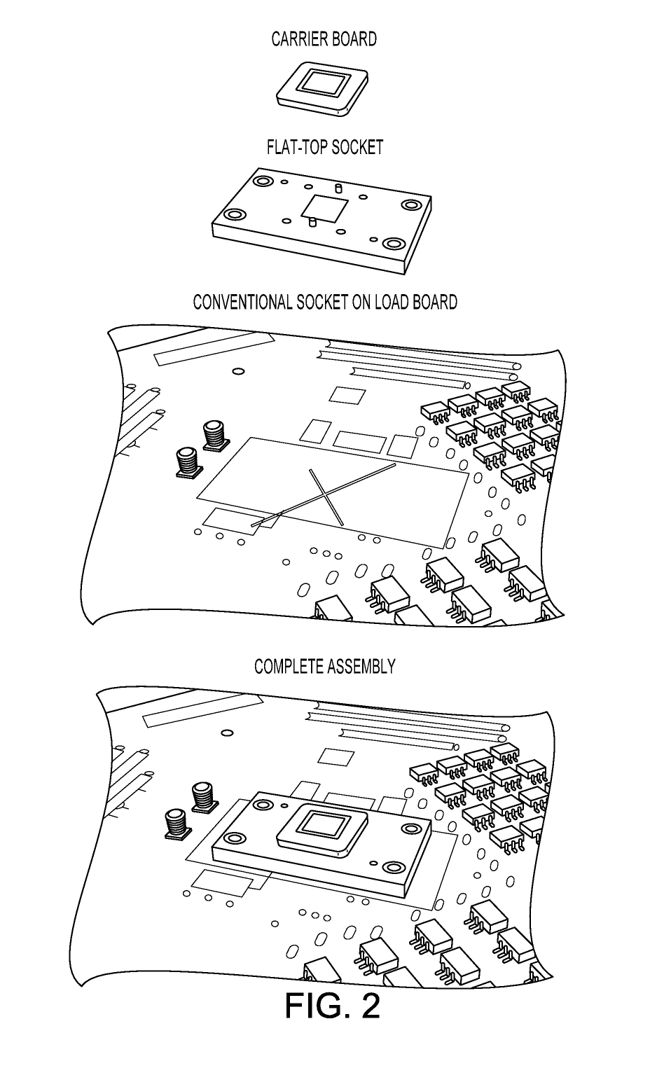

FIG. 2 illustrates a solution to the problems described above and provides an embodiment that does not press on the thinned die from the top and also allows the optical diagnostic tool to sit directly on the digital die. The embodiment includes a flat-top socket and a flat-top carrier board. The flat-top socket is a specially designed socket and has an array of pogo pins that match the solder ball array on the digital device to be tested. The flat-top carrier board is a small printed circuit board (PCB) with an array of pins on both sides. These pins are connected using through-vias. The array of the carrier board is the same as the solder ball array on the digital device. A pick and place machine is used to mount the device on the flat-top carrier board, in the same manner as conventional circuit boards are assembled. Electrical connections are formed with the device solder balls during the solder reflow process, however, the electrical connections may be formed using any suitable method. A low viscosity ultraviolet (UV) cured epoxy is applied in the gap between the flat-top carrier board and the device. The epoxy surrounds the solder balls. After application, the epoxy is cured, providing a solid and secure mechanical and electrical bond.

The back side of the flip-chip die is then exposed by parallel lapping and is then polished using a polishing machine. The flat-top socket has an array of pogo pins as would a traditional socket. The flat-top carrier board with the mounted and prepared package is mounted on the flat-top socket using four threaded holes. The bottom-side solder pads of the carrier board make electrical contact with the pogo pins on the flat-top socket. During testing the optical diagnostic tool of the analysis tool is able to come into contact with the backside of the die and may travel to any location on the back surface of the die.

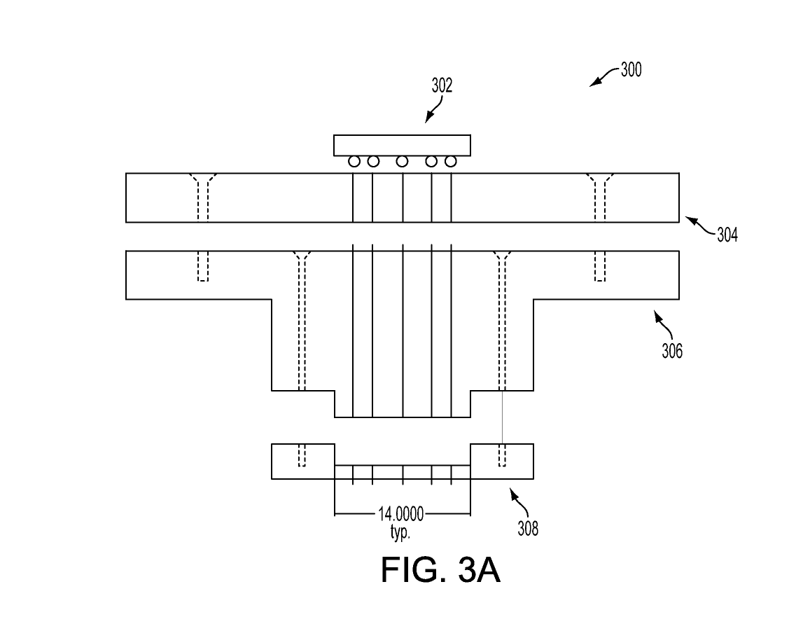

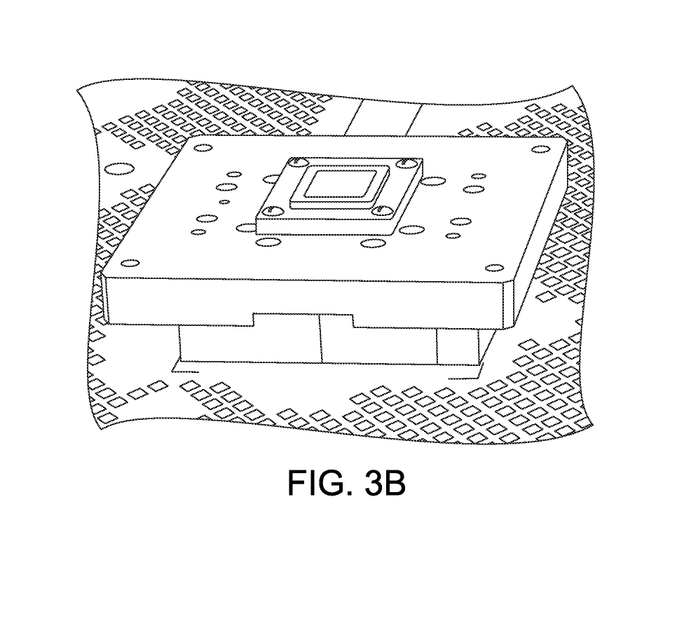

FIG. 3A and FIG. 3B shows the relationship of the flip-chip, flip-chip carrier, flip-chip socket, and existing ball grid array (BGA) socket in an embodiment. The assembly, 300 includes the components described below. The flip-chip 302 is placed onto the flip-chip carrier 304. Flip-chip carrier 304 is mated with flip-chip socket 306. Flip-chip socket 306 mates with the existing BGA socket 308. FIG. 3A shows a side view of the flip-chip, flip-chip carrier, flip-chip socket, and BGA prior to assembly. FIG. 3B shows the completed assembly installed.

In use, flip-chip package 302 is affixed to flip-chip carrier board 304. The flip-chip 302 is then parallel lapped to expose the die. The flip-chip socket 306 is then mounted on an existing BGA socket 308. Flip-chip carrier board 304 with the mounted and prepared flip-chip 302 is then mounted on the flip-chip socket 306. The optical diagnostic tool is then allowed to come into contact with the backside of the die and may travel to any location on the back of the die as needed.

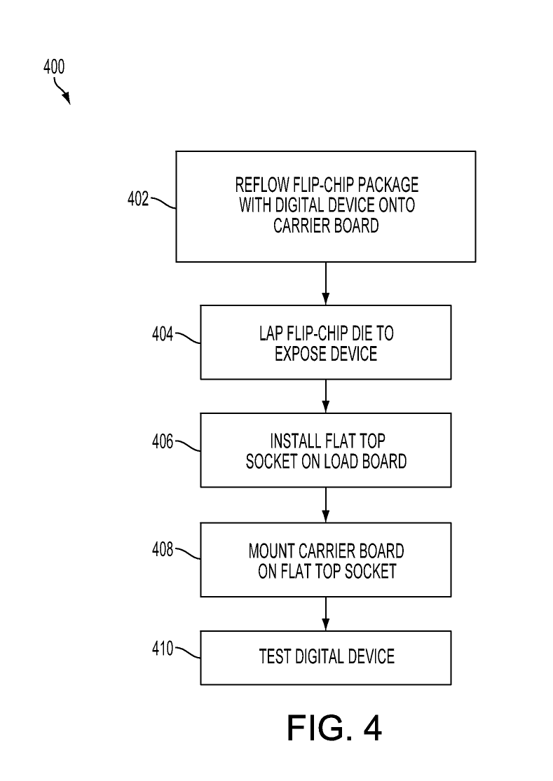

FIG. 4 is a flowchart of the steps involved in a method of testing a digital device. The method, 400 begins when a flip-chip package with a digital device is affixed to a carrier board in step 402. The flip-chip is then lapped to expose the digital device in step 404. In step 406 the flat-top device is installed on the load board. The carrier board is then mounted on the flat-top socket in step 408. At this point in the method, the installation is complete and the testing process begins in step 410, with the optical diagnostic tool accessing all areas of the digital die.

In an alternative embodiment, a flip-chip socket and carrier board, is used. This embodiment does not press on the thinned die from the top, thus eliminating the die cracking problem. In addition, the assembly permits the optical diagnostic tool to rest directly on the digital die as the polished die is at the highest level of the test assembly and is not obstructed. FIG. 3 depicts the embodiment. The existing socket need not be removed from the load or test board. In addition, wafer level packages may be handled using the carrier board, eliminating potential die breakage during handling.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. An apparatus for facilitating testing of a digital device, comprising:
a flip chip socket having a recess for accepting a carrier board, the recess having electrical contacts disposed in a pattern matching a pattern on a digital device; and
a flat-top carrier board having electrical contacts disposed in a pattern matching the pattern of the digital device electrically connected to the digital device.

2. An apparatus for facilitating testing of a digital device, comprising:
a digital device electrically and mechanically attached to a flip-chip carrier; and
a flip-chip socket having an interface for connecting with the flip-chip carrier and an existing socket.

3. The apparatus of claim 2, where the existing socket is a ball grid array socket.

4. A method of testing a digital device, comprising:
affixing a flip-chip package containing a digital device onto a carrier board;
exposing the flip-chip die by parallel lapping;
installing a flat-top socket on a load board;
mounting the carrier board on the flat-top socket; and
testing the digital device.

5. The method of claim 4, wherein testing the digital device uses an optical diagnostic tool.

6. An apparatus for facilitating testing of a digital device, comprising:
means for affixing a flip-chip package containing a digital device onto a carrier board;
means for exposing the flip-chip die by parallel lapping;
means for installing a flip chip socket on a load board;
means for mounting the carrier board on the flip chip socket; and
means for testing the digital device.

7. The apparatus of claim 6, wherein the means for testing using an optical diagnostic tool.

8. The apparatus of claim 1, further comprising an interface between the carrier board and the flat-top socket recess.

9. The apparatus of claim 1, wherein the interface between the carrier board and the digital device is a flat-top socket.

10. The apparatus of claim 1, wherein the interface between the carrier board and the digital device incorporates an elastomer.

11. A non-transitory computer readable medium containing instructions, which when executed by a processor cause the processor to perform the steps of:
activating an optical diagnostic tool;
positioning the optical diagnostic tool over a digital device affixed to a flip chip carrier board and electrically connected to a flip chip socket in turn electrically connected to a flip chip carrier board and a load board; and
accessing the digital device for testing using the optical diagnostic tool.
